(19) United States
(12) Patent Application Publication
(10) Pub. No.: US 2011/0189379 A1
(43) Pub. Date: Aug. 4, 2011

(54) METHOD FOR THE THERMOGRAPHIC INSPECTION OF NONMETALLIC MATERIALS, PARTICULARLY COATED NONMETALLIC MATERIALS, AS WELL AS METHOD FOR THE PRODUCTION THEREOF AND AN OBJECT PRODUCED ACCORDING TO THE METHOD

(76) Inventors: Andreas Ortner, Gau-Algesheim (DE); Klaus Gerstner, Mainz (DE); Ralph Neubecker, Dreieich (DE)

(21) Appl. No.: 12/935,221

(22) PCT Filed: Apr. 13, 2009
(86) PCT No.: PCT/US09/02284

§ 371 Date: Mar. 3, 2011

(30) Foreign Application Priority Data
Mar. 28, 2008 (DE) 10 2008 016 272

(51) Int. Cl. G01N 25/72; C23C 14/54; C23C 14/28; B05D 3/02

(52) U.S. Cl. 427/9; 374/5; 427/595; 427/376.2

(57) ABSTRACT

A method for the thermographic inspection of nonmetallic materials, particularly coated nonmetallic materials, is provided. The method includes heating at least one part of the surface of the nonmetallic material, preferably a part of the surface furnished with a nonmetallic coating, by a short energy pulse, preferably a light pulse, or by periodic input of heat, and recording the temporal and spatial temperature profile at least at a plurality of successive time points.

### CROSS REFERENCE TO RELATED APPLICATIONS

This application is a U.S. National Stage Entry under 35 U.S.C. §371 of International Application No. PCT/EP2009/002284, filed on Mar. 28, 2009, which claims benefit under 35 U.S.C. §119 of German Patent Application No. 10 2008 016 272.8, filed Mar. 28, 2008, the entire contents of both of which are incorporated herein by reference.

### BACKGROUND OF THE INVENTION

1. Field of the Invention

The invention relates to a method for the thermographic inspection of nonmetallic materials, particularly coated nonmetallic materials.

2. Description of Related Art

Methods for thermographic inspection have been used to date, for example, for the inspection of metallic materials for flaws of the material itself or of coatings applied to the material.

WO 2006/037359 A1 discloses a thermographic method in which the temporal profile of the surface temperature is analyzed, with this analysis being undertaken as a function of time logarithms and temperature logarithms. Investigated as materials are metallic materials, such as, for example, turbine blades.

Known from the article “Automatisches System zur thermographischen Prufung von Gasturbinenschaufeln” [Automatic System for the Thermographic Inspection of Gas Turbine Blades], W. Heinrich et al. DGZfP-Jahrestagung [Annual Meeting of the German Society for Non-Destructive Testing] 2003 ZfP Anwendung, Entwicklung and Forschung [Non-Destructive Testing Application, Development, Research], is the thermographic inspection of coated turbine blades.

Owing to the high thermal conductivity of the metal in comparison to the very reduced thermal conductivity of the coating, the thermographic measurement of coated metallic objects affords a quite acceptable temporal temperature profile for determining material parameters.

However, a problem has hitherto existed in inspecting or even measuring the thickness or completeness of a coating application of thin nonmetallic layers on nonmetallic materials, such as, for example, protective layers on ceramic materials.

This problem is generally found to be all the more difficult as these layers become more similar. In particular, ceramic layers or layers containing particles, including sintered particles, can barely be distinguished optically or are not at all distinguishable from the coated ceramic substrate, for example.

The invention is based on the problem of enabling or improving the inspection or even the measurement of coating applications, particularly nonmetallic coating applications on nonmetallic materials.

Surprisingly, the inventors have found that thermographic methods may also be used to investigate nonmetallic materials that can be coated, even nonmetallically coated.

In spite of the poor thermal conductivity of both the material and its coating, the inventors have found that thermography may be used to obtain conclusive and, moreover, results that can be calibrated as well as metrologically useful results.

A very important application of this method is found in the inspection of fused quartz crucibles furnished with a barrier coating, such as, for example, fused quartz crucibles for silicon production.

Silicon is often melted in fused quartz crucibles coated with silicon nitride to produce silicon bars, which are also referred to as ingots. The silicon nitride coating prevents the fused silicon from entering into reaction with the crucible material and damaging or even penetrating through the crucible.

The production of such fused quartz or similarly coated crucibles is described, for example, in DE 10 2005 029 039 A1, WO 2006/005416 A1, DE 103 42 042 A1, EP 1 570 117 B1, WO 2007/003354 A1, WO 2005/106084 A1, DE 10 2005 050 593 A1, EP 0 963 464 B1, WO 98/35075, U.S. Pat. No. 6,479,108 B2, WO 2006/107769 A2, U.S. Pat. No. 5,431,869, DE 10 2007 015 184 A1, US 2007/0074653 A1, U.S. Pat. No. 4,741,925, U.S. Pat. No. 6,491,971 B2, WO 2007/039310 A1, WO 2004/053207, US 2002/146510, US 2002/083886 A1.

The inspection method hitherto used for evaluating the protective layer quality is composed of a visual inspection during the spraying of the first layer using a silicon nitride slurry, which subsequently undergoes fixation by a thermal process.

The optical inspection had to be conducted during the spraying, because, after thermal fixation, this layer can nearly no longer be perceived using visual means. This process applies essentially a thin white film on a white substrate.

Silicon nitride slurry is understood here to refer to any viscous liquid mixture in which silicon nitride is dispersed and/or dissolved.

Further known was the investigation of these layers after spraying by means of a spot-check-like scratch test, which resulted, however, in the destruction of the layer at least at the respective site of the test.

In view of the high-risk situation for humans and material during the production of silicon, there existed a very great need for improvement in the available inspection and measurement methods, particularly for this application.

Not only immensely high costs for loss of a crucible and its material but also the danger due to liquid silicon leaking out at very high temperature make clear the need for these improved methods.

An inspection and metrological problem thus existed for this very material-layer system combination in that the thin coating application could hardly be distinguished optically from the underlying ceramic support material.

In addition, particularly the inhomogeneities presumed to be present in the layers applied by means of slurries cast a critical light on thermal methods and their conclusiveness, particularly for measuring the thickness of such a layer.

Consequently, there initially also existed the presumption that thermal measurements, particularly in the infrared spectral region, would not provide any significant results, and the inventors were all the more surprised when they obtained the results described below.

The invention provides a method for the thermographic inspection of nonmetallic materials, particularly coated nonmetallic materials, in which at least one part of the surface of the nonmetallic material, preferably a part of the surface furnished with a nonmetallic coating, is heated, in particular, by means of a short energy pulse, preferably a light pulse, or by periodic heat input, and the temporal and spatial temperature profile is recorded at least at a number of successive time points.

Furthermore, the invention also provides objects produced according to the invention, the layers of which have only a deviation of less than 20 μm, usually even less than 5 μm, from their specified layer thickness, this being of great advantage particularly for barrier coatings.

It was advantageous here to record using an imaging infrared camera in a temporally and spatially resolved manner, because, in this way, flawed regions or regions of inadequate coating thickness could be detected immediately.

Advantageously, the Fourier transformation of the recorded temporal temperature profile was determined in a spatially resolved manner and displayed in a spatially resolved manner for one time point t or one defined phase following the input of the energy pulse so as to determine thereby the thermal diffusion of the energy or heat pulse through the layer and, on the basis thereof, its thickness.

To this end, the convolution signal of the temporal profile of the energy pulse with the recorded temporal temperature profile could also be determined in a spatially resolved manner for a shift time point t and displayed in a spatially resolved manner.

In a particularly preferred embodiment, the coating was applied using a suspension containing water and particles, particularly sinterable particles, in particular a slurry, preferably by spraying, brushing, rolling, dipping, and/or by condensation of a laminar film, and subsequently subjected to a thermal fixation process.

In this embodiment, the sinterable particles preferably comprise silicon nitride and/or the ceramic material comprises an SiO₂-containing ceramic, in particular, Quarzal.

It was particularly advantageous when, in this case, the thermographic inspection was carried out prior to the thermal fixation process, since it could then be ensured, before the thermally stressing and energy-cost-intensive fixation operation, that the requisite minimum layer thickness existed at all sites of the coating.

The inventors have further found that it is very important to carry out a drying step prior to the thermographic inspection, particularly when no thermal fixation was carried out. Without this step, serious variations were found in the results, which would have led to dramatic erroneous evaluations of the layer thicknesses as well as of the intactness of the layer system. Furthermore, it was possible to observe the drying process, because, during drying, the values of the layer thickness changed constantly until the layer thickness reached a stable limit in the essentially dry state.

Preferably, to this end, a drying step was carried out at a temperature of greater than 20° C. and for a time period of greater than 2 h, preferably greater than 3 h, and, most preferably, greater than 5 h.

The measurement was also surprisingly conclusive when the nonmetallic material comprised a ceramic and the coating a barrier coating.

Even when the ceramic comprised fused quartz, such as, for example, Quarzal, and the barrier coating comprised a silicon nitride layer, which are nearly indistinguishable optically from each other, it was still possible to obtain metrologically relevant results.

In a preferred embodiment, the ceramic had a wall thickness of about 5 mm to 50 mm at the coated site and the silicon nitride coating had a thickness of 50 μm to 500 μm.

In the most preferred embodiment, the ceramic had a wall thickness of about 15 mm at the coated site and the silicon nitride coating had a thickness of 100 μm to 300 μm.

Even when the layer system was a multilayer system, it was possible to obtain relevant conclusions of the inspection method, without the multilayer construction falsifying the measurements to an appreciable extent in this case.

In the preferred embodiment, the multilayer system comprised silicon nitride layers that were initially applied by means of a slurry on the ceramic, layer by layer, and subsequently were fixed by a thermal fixation process.

The method was surprisingly well applicable also when the material had the form of a preferably rectangular crucible, because, in this case, unexpectedly precise results were obtained even at oblique angles as, for example, in the crucible corners.

In a particularly simple method embodiment, a threshold value at a defined time point after the energy input could be specified beforehand for the coating layer thickness to be inspected and could be used as a measure for a minimum layer thickness for inspecting each site of the coating.

Because the inventors were able to obtain such good results using the thermographic inspection method according to the invention, particularly also with the drying steps, a successful effort was made to use this inspection method also for measurement purposes.

For this purpose, reference measurements were carried out on a test object that comprised a nonmetallic material, the test object having layers of various prespecified layer thicknesses at various sites and the values assigned to these prespecified layer thicknesses being determined for calibration of the measured values.

Afterwards, it was possible to obtain, in an advantageous and surprisingly precise manner, spatially resolved measurement of the layer thickness of a nonmetallic layer on a nonmetallic object, for which the layer thickness could be determined in a spatially resolved manner by comparison and/or interpolation of the values determined and calibrated beforehand.

In this case, a layer thickness resolution of 20 μm was established in a surprisingly precise manner for a system containing a silicon nitride layer on a fused quartz—particularly, a Quarzal—bject. 20 μm was the smallest measurement or height difference, that is, depth change measured directly by the camera, realized in a step sample. The calibrating curve determined later shows, purely by calculation, a value of the resolution of 1 μm per gray-scale value change. Consequently, the maximally achievable resolution of the layer thickness measurement was, in fact, only about 1 μm in a surprisingly good manner. However, resolutions of better than 5 μm were practically always obtained.*

Surprisingly good also were the results for three-dimensional objects, in particular, ceramically coated ceramic objects; these were also able to satisfy the aforementioned metrological resolution. It was not clear that an illumination generating the heat pulse and, at the same time, such a precise measurement are still possible when the measured object does not have a two-dimensional, that is, flat, extension, but rather has a three-dimensional extension, that is, for example, portions which, as is the case for a crucible—for example, its side walls—are arranged perpendicularly or at an angle in relation to its base.

The invention also comprises a method for producing a nonmetallic object having a nonmetallic coating, a method for thermographic inspection, and a method for measuring layer thickness, as will be described in detail below.

It also finds use particularly for ensuring a minimum layer thickness of the nonmetallic layer on the nonmetallic object, such as, for example, of barrier layers. In this way, it is possible to lower costs as well as prevent dangers, because flawed production results are minimized and layer thicknesses can be provided at a high quality level.

The nonmetallic objects having nonmetallic coating that are produced and can be produced according to the invention are also part of the present invention.

With these surprisingly good results, the invention also provides objects produced according to the invention, the layers of which only have a deviation of less than 20 μm, usually even less than 5 μm, from their specified layer thickness, since it is possible to make subsequent improvements at not yet correctly applied sites in an iterative manner and, during the recording of the imaging values, to do so, in fact, in an automated manner.

The invention will be described below in more detail with reference to the attached figures on the basis of preferred embodiments.

### BRIEF DESCRIPTION OF THE SEVERAL VIEWS OF THE DRAWINGS

FIG. 1 typical absorption bands in the near-, middle-, and far-infrared spectral region, such as those, for example, that can be obtained in the atmosphere,

FIG. 2 a typical thermographic structure by means of which measurements can be carried out by way of example for the invention,

FIG. 3 a thermographic image of the phase difference (hence, after Fourier transformation) of a fused quartz object partially coated with a silicon nitride layer, obtained in the thermographic structure shown in FIG. 2,

FIG. 4 an illustration of the temperature profile as a function of time for diffusion of a Dirac temperature pulse into a semi-infinite homogeneous medium containing a component which triggers a build-up of heat, starting from its surface,

FIG. 5 a double logarithmic illustration of the temperature profile as a function of time for diffusion of a Dirac temperature pulse into a semi-infinite homogeneous medium containing a component that triggers a build-up of heat, starting from its surface,

FIG. 6 a two-dimensional illustration of the height step of a fused quartz or Quarzal object, measured using a white-light interferometer, which, as for the object in FIG. 3, is coated partially with a silicon nitride layer, with a drawn line that runs transverse to a coated section and a non-coated section of its surface,

FIG. 7 a mean height profile calculated from the two-dimensional white light interferometer image of FIG. 6, which extends along the line shown in FIG. 6,

FIG. 8 in its upper region, a two-dimensional illustration of the local intensity profile, measured by pulse thermography, at the surface of a fused quartz, particularly Quarzal, object that is coated with several silicon nitride layers, which increase in number at the surface of the Quarzal object and hence in their total thickness, step by step, on going from left to right, as well as, in its lower section, individual measurements, illustrated by way of example, carried out using a confocal reference measurement method for determining the true height steps and carrying out the calibration of the calibrating curves, which, among other things, were obtained with the fused quartz, particularly Quarzal, objects (and others) illustrated in FIG. 8, for which locally measured layer thicknesses of the silicon nitride layer applied to the Quarzal objects were assigned to the absolute gray-scale values obtained by pulse thermography,

FIG. 10 a two-dimensional illustration of a calibration similar to that illustrated in FIG. 9, for which the gray-scale values obtained by pulse thermography and hence layer thickness values thereof were determined for two different distances,

FIG. 11 the local intensity and hence layer thickness profile, measured by pulse thermography, at the surface of a fused quartz, particularly Quarzal, crucible that had no coating whatsoever, as viewed at an angle from above,

FIG. 12 the local intensity and hence layer thickness profile, measured by pulse thermography, at the surface of a fused quartz, particularly Quarzal, crucible that is coated completely with a silicon nitride layer, which was applied to it using a spray coating in a first coating step, as viewed at an angle from above,

FIG. 13 the local intensity and hence layer thickness profile, measured by pulse thermography, at the surface of the fused quartz, particularly Quarzal, crucible illustrated in FIG. 12, which, in addition, is coated completely with yet a second silicon nitride layer, which was applied onto the first layer in a second coating step by using a spray coating, as viewed at an angle from above,

FIG. 14 the local intensity and hence layer thickness profile, measured by pulse thermography, at the surface of the fused quartz, particularly Quarzal, crucible illustrated in FIG. 12 and FIG. 13, which, in addition, is coated completely with yet a third silicon nitride layer, which was applied onto the second layer in a third coating step by using a spray coating, after a drying time of approximately 20 minutes following the third spray coating, as viewed at an angle from above,

FIG. 15 a photographic illustration of the fused quartz, particularly Quarzal, crucible illustrated in FIG. 14, as viewed at an angle from above, essentially viewed from the same direction as illustrated in FIGS. 11 to 13,

FIG. 16 the local intensity and hence layer thickness profile, measured by pulse thermography, at the surface of another fused quartz, particularly Quarzal, crucible that has a flawed silicon nitride layer, as viewed at an angle from above,

FIG. 17 the local intensity and hence layer thickness profile, measured by pulse thermography, at the surface of yet another fused quartz, particularly Quarzal, crucible that has an intact silicon nitride layer, as viewed at an angle from above,

FIG. 18 the temperature distribution on a fused quartz, particularly Quarzal, object coated with six different layer thicknesses.

### DETAILED DESCRIPTION OF PREFERRED EMBODIMENTS

When fused quartz crucibles are coated with barrier layers, particularly with ceramic barrier layers, the layer quality, that is, the presence of a minimum layer thickness, its intactness, and the absence of cracks and detachment from the surface, take on crucial importance.

The investigation of crucibles already used for silicon production can also substantially increase their service life, if it can be established with certainty that these crucibles still have the required minimum layer thickness for the ingot production operation at all necessary sites, in particular the sites coming into contact with silicon.

However, a particularly advantageous point in time also exists when this investigation is carried out prior to the thermal fixation process of the slurry applied onto the ceramic fused quartz, particularly Quarzal, object.

For one thing, each layer can then still be investigated with certainty in terms of its layer quality prior to the thermally stressing and energy-intensive and cost-intensive fixation operation and either released or else post-processed, this being extremely helpful particularly in the case of spatially resolved measurements.

First of all, however, the inventors established that, after the application of the slurry, no reliable measured values were to be obtained, because an assignment of the layer thickness values obtained by thermal measurements to values measured by alternative methods failed.

Alternative methods of measurement are, for example, microscopic (confocal) and electron microscopic measurement methods as well as scratch tests, which can be carried out on cut surfaces of the coated object, but not without destruction in the latter case, and hence are only poorly suitable for production.

The question arose as to whether inhomogeneities, cracks, thickness variations, compositional variations of the ceramic, or contaminations led to these erroneous measurements or whether thermal measurement methods were generally unsuitable for such ceramic layer systems.

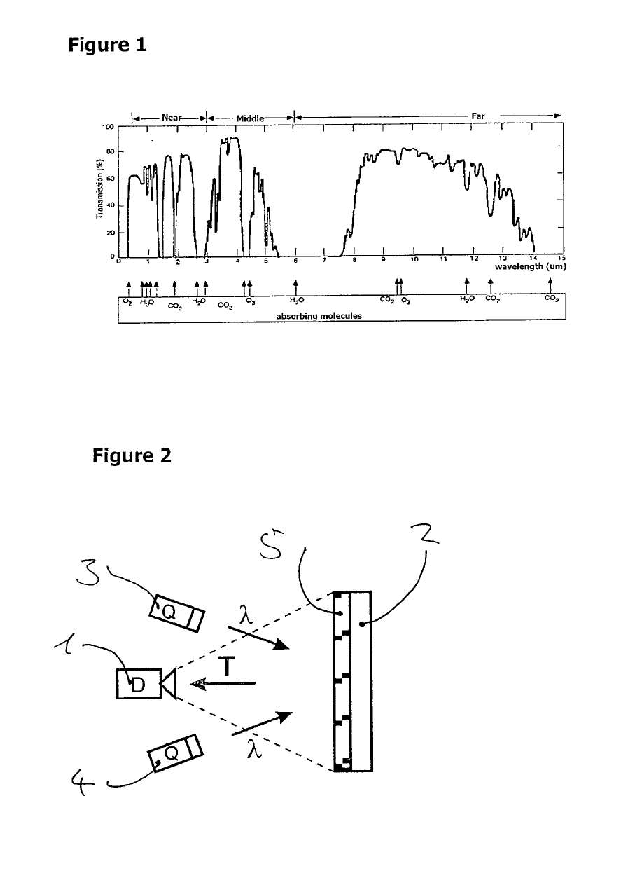

In the following, reference is made to FIG. 1, which shows, by way of example, typical absorption bands in the near-, middle-, and far-infrared spectral region, such as those obtained in the atmosphere, for example.

The inventors found that especially the solvent, particularly water, that was present in the slurry led to these appreciable measurement deviations, the absorption bands of which can be well recognized in FIG. 1.

Particularly in the case when no thermal fixation was carried out, a drying step carried out prior to the thermographic inspection could improve appreciably the quality of the measurements.

Without this step, however, serious variations in the obtained results were found and could have lead to dramatic erroneous evaluations of the layer thicknesses as well as of the intactness of the layer system.

Preferably, to this end, at least one drying step was carried out at a temperature of greater than 20° C. for a time period of greater than 2 h, preferably greater than 3 h, and, most preferably, greater than 5 h.

In the following, reference is made to FIG. 2, which, merely by way of example, shows the inspection structure by means of which measurements that are exemplary for the invention were carried out.

The reference numeral 1 is assigned to a thermal camera, which had a spatial resolution of about 600 times 500 pixels and which recorded the image of the surface of a ceramic object 2 provided with a coating 5.

The surface of the object 2 was illuminated as homogeneously as possible by means of flash devices 3 and 4 in order to ensure an energy input that is as homogeneous as possible over the surface of the object 2.

The flash devices 3 and 4 were operated synchronously with the thermal camera 1, so that a fixed temporal sequence of images of two-dimensional data could be recorded.

The momentary light output of all flash devices is defined here as the light pulse for the thermal energy input, regardless of whether this actually takes place absolutely simultaneously or else with a delay of a short amount of time.

The workpiece used for carrying out the method according to the invention was a ceramic fused quartz, particularly Quarzal, object, on the surface of which four differently coated regions I to IV were encountered; see, for example, FIG. 18.

The production of such essentially ceramically coated ceramics is described, by way of example, in DE 10 2005 029 039 A1, WO 2006/005416 A1, DE 103 42 042 A1, EP1 570 117 B1, WO 2007/003354 A1, WO 2005/106084 A1, DE 10 2005 050 593 A1, EP 0 963 464 B1, WO 98/35075, U.S. Pat. No. 6,479,108 B2, WO 2006/107769 A2, U.S. Pat. No. 5,431,869, DE 10 2007 015 184 A1, US 2007/0074653 A1, U.S. Pat. No. 4,741,925, U.S. Pat. No. 6,491,971 B2, WO 2007/039310 A1, WO 2004/053207, US 2002/146510, US 2002/083886 A1.

Wikipedia defines technical grade silicon nitride as a non-oxide ceramic that usually is comprised of β-silicon nitride crystals in a glassy rigidified matrix. The glass phase fraction reduces the hardness of Si₃N₄ in comparison to silicon carbide, but enables acicular recyrstallization of the β-silicon nitride crystals during the sintering operation, which brings about a markedly increased fracture toughness in comparison to silicon carbide and boron carbide. The high fracture toughness, in combination with small defect sizes, imparts to silicon nitride the greatest strength of ceramic engineering materials. The combination of high strength, low thermal expansion coefficient, and relatively small elasticity modulus makes Si₃N₄ ceramic particularly suitable for components subject to thermal shock, and it is employed, for example, as replaceable cutting insert for cast-iron materials (including those in interrupted cut) or for handling aluminum melts. Silicon nitride ceramics are suitable for application temperatures of up to about 1300° C. when a suitable refractory glass phase is chosen (for example, by adding yttrium oxide). This definition is also to apply for the purposes of the present invention.

Referred to as the silicon nitride layer for the purposes of the present invention is also a layer containing silicon nitride, which contains particulate non-sintered, particulate sintered, and/or ceramic constituents.

According to the free encyclopedia Wikipedia, whose definition is also used as the basis for this description, ceramics are largely articles that are formed from inorganic, fine-grain raw materials with addition of water at room temperature and afterwards dried, which, in a subsequent baking process above 900° C., are sintered to harder, durable articles. The term also encompasses materials based on metal oxides.

The same is to apply also for ceramic objects and ceramic layers for the purposes of this description as their definition.

The term Quarzal is understood in this description to be a high-SiO₂-containing refractory material, in particular, a high-SiO₂-containing ceramic, the SiO₂ fraction of which is greater than 98%. In the case of high-purity Quarzal, which is preferably used, the SiO₂ fraction is greater than 99.99%, with this material being produced as a sintered ceramic from an aqueous slurry and hence an aqueous, particulate SiO₂-containing suspension.

The region IV had no coating, whereas the coating in the regions III to I was increasingly thicker. See, for example, FIG. 18.

The coating thicknesses in the region I were about 70 μm, in the region II about 140 μm, and in the region III about 220 μm.

The coating was a barrier coating, which comprised, in particular, a silicon nitride layer, such as is employed, for example, in the production of silicon.

The various thicknesses were obtained by a multiple application of a silicon nitride slurry, which, subsequently, was baked on or underwent fixation on the surface by means of a thermal fixation process. This coating was applied using the suspension containing water and particles, particularly sinterable particles, preferably by spraying, brushing, rolling, dipping, and/or condensation of a laminar film.

For the purposes of the fabrication, the coating was subjected subsequently to a thermal fixation process.

In this embodiment, the particles preferably comprise silicon nitride and/or the ceramic material comprises a SiO₂-containing ceramic, in particular Quarzal.

The thermographic image of the surface of the Quarzal piece 2, directly following an energy input by means of a light pulse of the flash devices 3 and 4, showed, directly following the light exposure, nearly no differences in the intensity recorded by the various pixels of the thermal camera. See for this, for example, also FIG. 18.

As a result, the surprisingly homogeneous heating of the entire surface is readily detected. Also readily detected is that the surface was heated essentially identically both at the sites furnished with the coating 5 and at the sites without any coating.

The thermographic image of the surface of the Quarzal piece at a defined time point following the light pulse showed an intensity profile that could be assigned locally to the layer thickness, because, with increasing layer thickness, the intensity recorded by the individual pixels of the thermal camera 1 also increased.

This first test, initially not illustrated in the figures, was further developed more precisely as described in detail below.

An InSb quantum detector having a pixel count of 640×512 pixels was used, such as the one marketed by the company Thermosensorik GmbH.

The measurements were carried out using the InSb quantum detector (Model InSb 640 SM) of the company Thermosensorik GmbH. The FPA (focal plane) camera affords a resolution of 640×512 pixels with a readout frequency of 100 Hz for the full image, which can be increased by limiting the image field to up to 1000 Hz. The InSb detector is sensitive in the wavelength range of 1 μm to 5 μm, which is limited by the limited transmission behavior of the 28 mm objective used in the range of 3 μm to 5 μm. Two high-power flash lamps having a total energy of 12 kJ served as light sources.

The flash duration was somewhat greater than 10 ms, the intensity or the maximum energy input of the flash devices was 12 kJ per pulse, and the distance of the flash devices from the measured surface lay between 20 and 40 cm.

During the measurement, a video sequence was recorded by the camera over an adjustable time period: The sequence comprises a short time period prior to triggering the flash, the flash itself, and the subsequent cooling of the sample.

After a series of preliminary tests, the sequence length was set at 300 images for an imaging frequency of 100 Hz. The measurements were carried out with a maximum flash power of 12 kJ.

Advantageously, the Fourier transform of the recorded temporal temperature profile was determined in a spatially resolved manner and displayed in a spatially resolved manner for a time point t or a defined phase following the input of the energy pulse in order to determine in this way the thermal diffusion of the energy or heat pulse through the layer and, on the basis thereof, its thickness.

To this end, the convolution signal of the temporal profile of the energy pulse with the recorded temporal temperature profile could also be determined advantageously for a shift time point t in a spatially resolved manner and displayed in a spatially resolved manner.

For these purposes, the short illumination duration of the flash devices represented essentially a Dirac pulse in mathematical approximation.

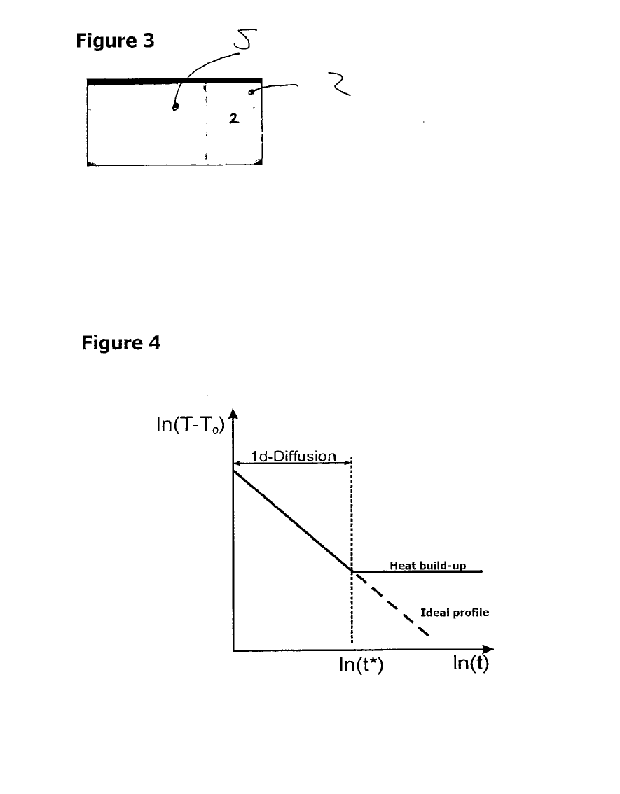

In the following, reference is made to FIG. 3, in which a Quarzal object 2, coated with a silicon nitride layer 5, is illustrated.

The thermographic structure illustrated in FIG. 2 was used for this image.

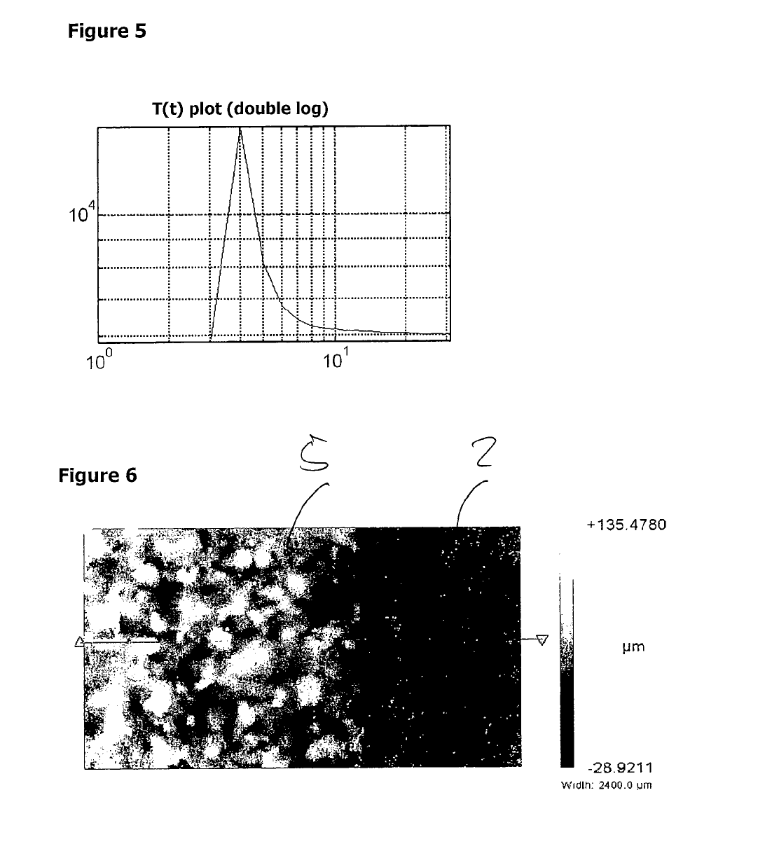

FIG. 4 shows an illustration of the temperature profile for diffusion of a Dirac temperature pulse into a semi-infinite homogeneous medium containing a constituent triggering a heat build-up starting at its surface as a function of time, and FIG. 5 shows a double logarithmic illustration of the temperature profile for diffusion of a Dirac temperature pulse in a semi-infinite homogeneous medium containing a constituent triggering a heat build-up starting from its surface as a function of time, with the location of the heat build-up being assigned to the peak in FIG. 5.

FIG. 6 shows a two-dimensional illustration of the layer thickness profile, measured using a white-light interferometer, at the surface of a Quarzal object 2, which is partially coated with a silicon nitride layer 5, along a coated section and along a non-coated section of its surface.

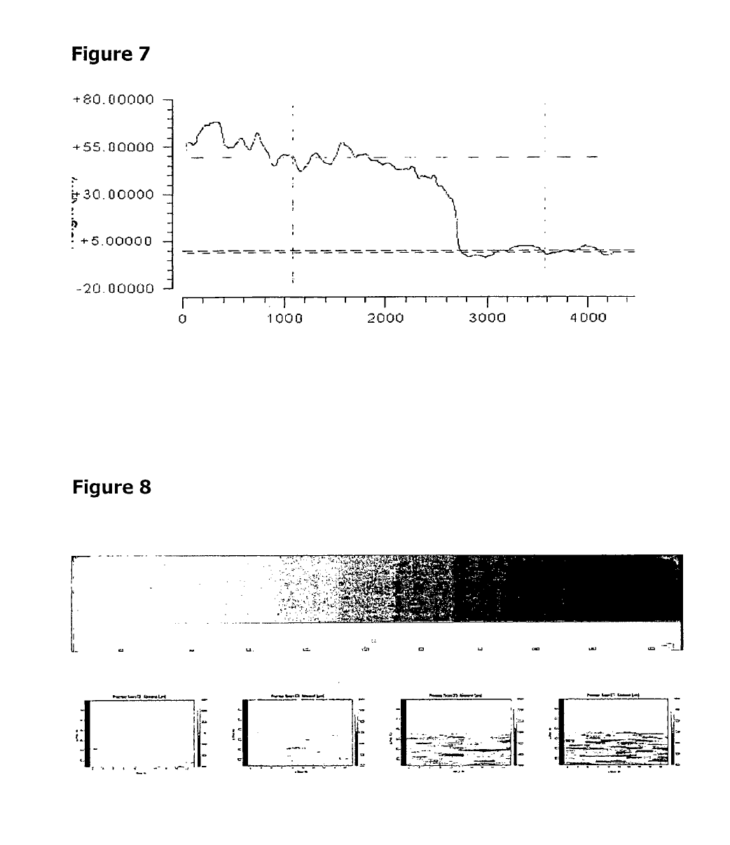

FIG. 7 shows the local layer thickness and height profile, measured using a white-light interferometer, along the line drawn in FIG. 6, which runs transverse to a coated section and a non-coated section.

However, non-destructive white-light interferometry can be used only for small surfaces and for essentially two-dimensional objects, that is, objects that have only a few micrometers of height difference, and is consequently not suitable for larger surfaces and three-dimensional objects, which have a greater height difference.

Furthermore, interferometers have to be calibrated, in the wavelength range both in terms of distance and with respect to their tilt in relation to the measured surface, with a precision that practically rules out their use for serial manufacture.

Because, during thermography, the heat pulse runs, without further ado, but by itself, from the surface into the interior of the material and because the flash duration is so short that the energy input occurs essentially simultaneously everywhere on the illuminated surface, this pulse runs, as a rule, inherently perpendicular to the surface into the volume and the infrared camera and also the flash devices or lamps used for illumination need not be aligned precisely with respect to this surface to be measured. Furthermore, as a result of the Fourier transformation or convolution that is performed, essentially the shape of the signal is measured and less so its absolute value. But it is precisely the shape thereof that is crucial for the measured layer thickness, as will be shown at a later place.

However, a pure time-offset measurement, in which only the recording of the temperature distribution at a defined time point after the triggering of the flash devices took place, was also possible according to the invention, and could provide acceptable, but not actually calibratable measurement results. To this end, see also the example of FIG. 18.

Consequently, for the layer thickness of the coating to be examined, it was possible to specify beforehand a threshold value, which, in this case, is an intensity threshold value for the individual pixels, at a defined time point following the energy input, which could be specified beforehand and used as a measure for a minimum layer thickness for the inspection for each site of the coating.

Beyond the pure measurement of a minimum layer thickness, this method proved to be surprisingly precise and even allowed a calibration based on a multiply coated sample object with locally different layer thicknesses.

In the sense of this description, the term inspection comprises also a measurement, in particular a measurement based on a calibration, as will be described in more detail below.

FIG. 8 shows, in its upper area, a two-dimensional illustration of the local intensity profile, measured by pulse thermography as described above, at the object of a Quarzal object, which is coated with several silicon nitride layers, which, going from left to right, increase stepwise in their number at the surface of the Quarzal object and hence increase in their total thickness, as well as, in their lower area, individual measurements, which were undertaken for calibration purposes using a confocal reference method at the individual steps of this object. By way of example, however, only individual ones were shown. Used for the confocal reference measurement was a method such as that described, for example, in DE 10 200 40 49541.

The reference measurements were carried out on this sample object or on several sample objects, with values assigned to these prespecified layer thicknesses being determined for calibration of the measured values.

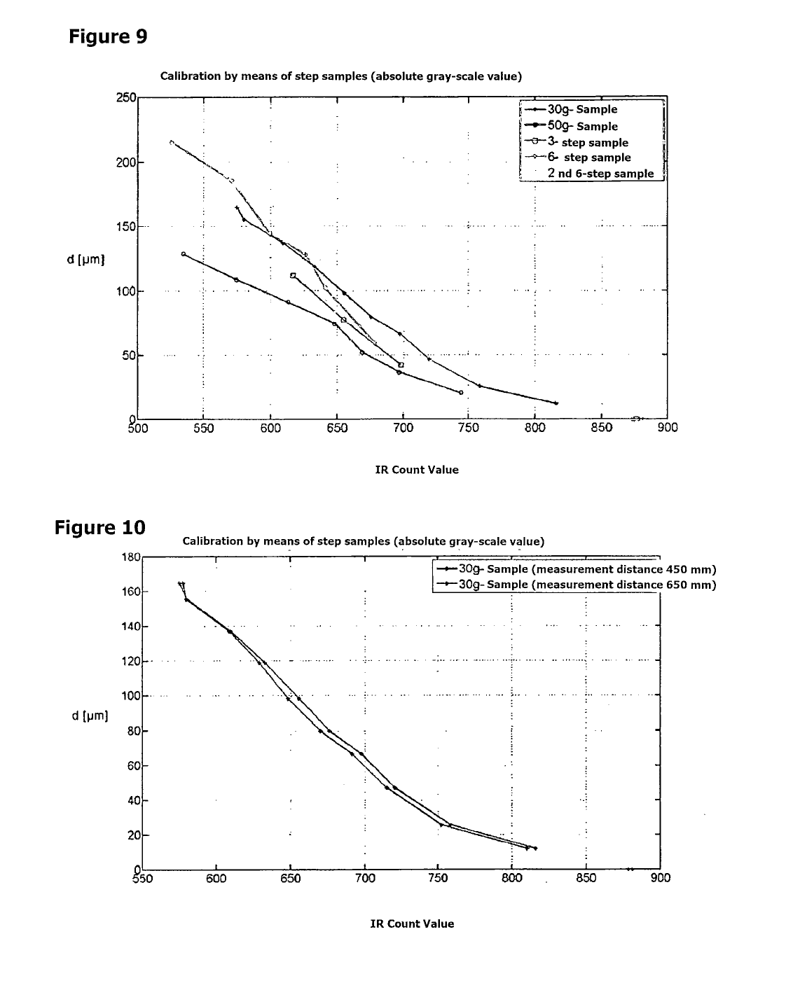

The respective sample object had layers of various prespecified layer thicknesses at various sites, which, in FIGS. 9 and 10, for example, are illustrated as measured points on their respective abscissas.

The ordinates of FIGS. 9 and 10 each show values referred to as IR count values, which, in terms of their numerical value, correspond to the value of the previously described Fourier signal and similarly also to the value of the described convolution signal.

FIG. 9 shows a two-dimensional illustration of a calibration obtained using the fused quartz, particularly Quarzal, objects illustrated FIG. 8, for which locally measured layer thicknesses of the silicon nitride layer applied to the Quarzal object were assigned to absolute gray-scale vales obtained by pulse thermography.

The layer thickness of a layer to be measured can then be obtained by comparison and/or linear interpolation for each location by using the calibrated values illustrated in FIG. 9, for example.

FIG. 10 shows a two-dimensional illustration of a calibration similar to that shown in FIG. 9, for which the absolute gray-scale values obtained by pulse thermography and hence their layer thickness values were determined for two different distances.

The two images were obtained for a distance of the infrared camera to the measured surface of 450 mm and 650 mm, respectively, and show very clearly that this distance has only a very small influence on the measured layer thickness.

Accordingly, this method is also found to be outstandingly suitable for the measurement of three-dimensional objects.

The spatial resolution in the lateral direction and hence essentially parallel to the surface of the sample object was about approximately 50 pixels (points) per cm and in the direction perpendicular to the surface of the sample object and hence in its depth about 20 μm, as explained above.

It was further possible to detect inclusions or local regions that were situated under the layer and did not have contact with the substrate, even when these had not yet led to cracks or otherwise optically detectable changes.

Shown in the following are additional measurement examples, which were provided according to the invention.

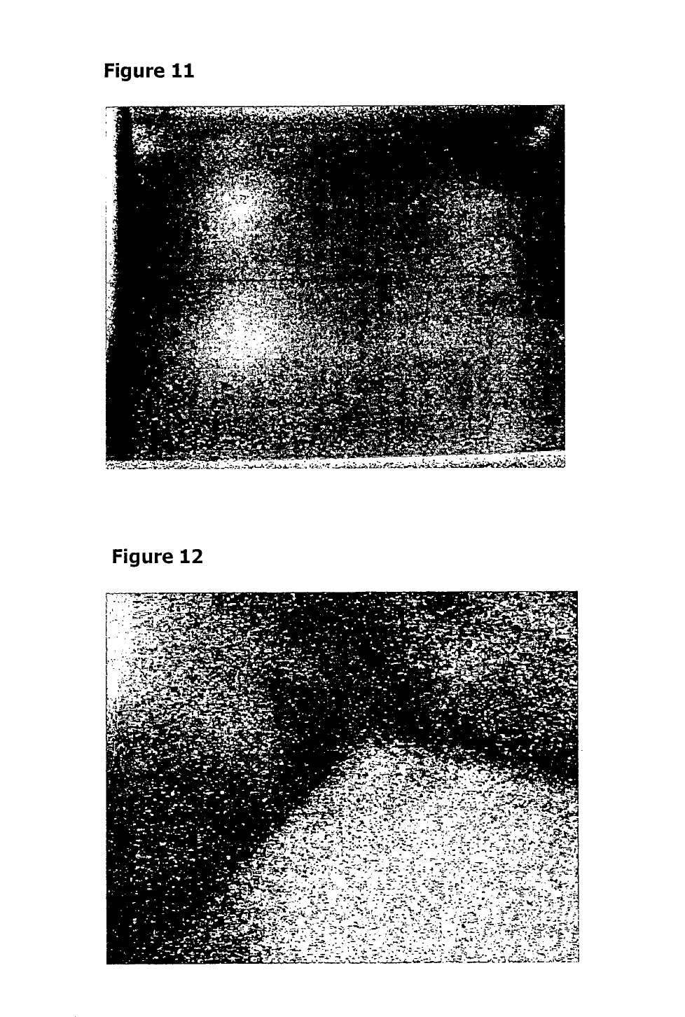

FIG. 11 shows the local intensity profile and hence the layer thickness profile, measured by pulse thermography, at the surface of a Quarzal crucible that had no coating whatsoever, as viewed at an angle from above.

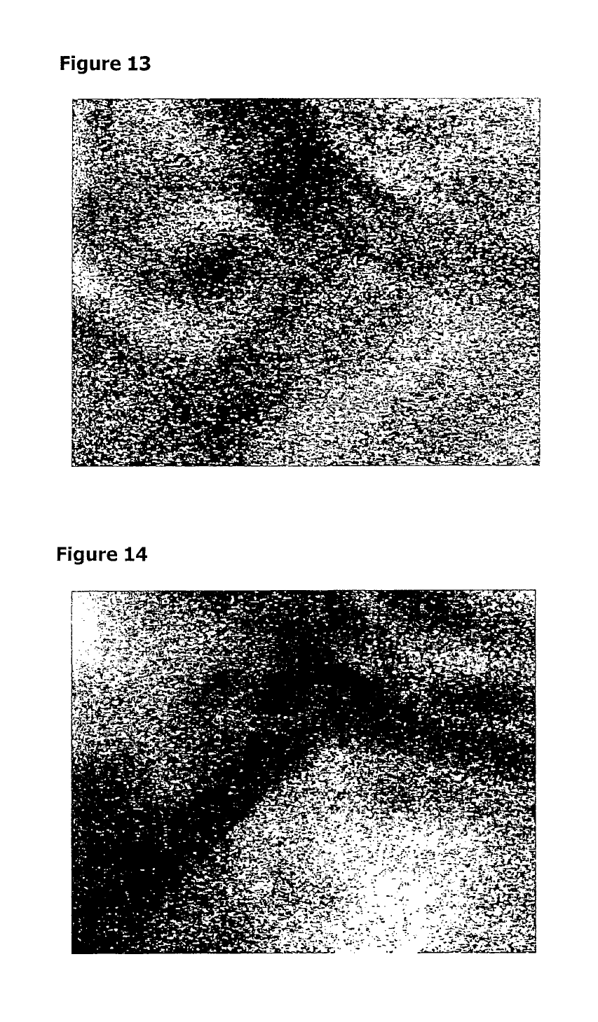

FIG. 12 shows the local intensity profile and hence the layer thickness profile measured by pulse thermography, at the surface of a Quarzal crucible that is coated completely with a silicon nitride layer, which was applied using a spray coating in a first coating step, as viewed at an angle from above; FIG. 13 shows the local intensity profile and hence layer thickness profile, measured by pulse thermography, at the surface of the Quarzal crucible illustrated in FIG. 12, which, in addition, is coated completely with a second silicon nitride layer, which was applied to the first layer in a second coating step using a spray coating, as viewed at an angle from above; and FIG. 14 represents the local intensity profile and hence the layer thickness profile, measured by pulse thermography, at the surface of the Quarzal crucible illustrated in FIG. 12 and FIG. 13, which is additionally coated completely with a third silicon nitride layer, which was applied to the second layer in a third coating step using spray coating, after a drying time of approximately 20 minutes following the third spray coating, as viewed at an angle from above;

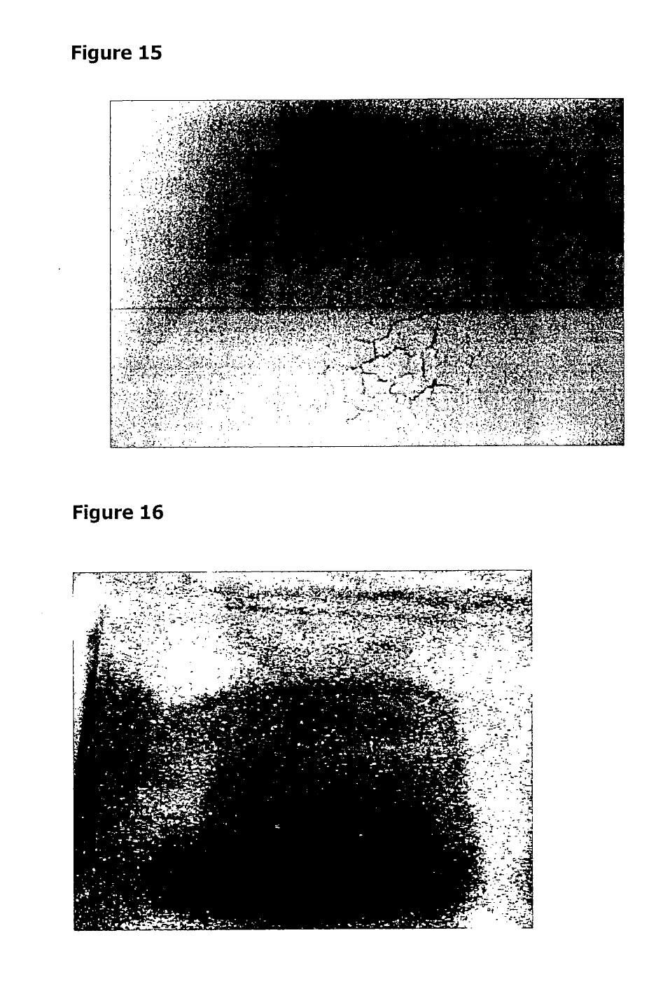

FIG. 15 shows a photographic illustration of the Quarzal crucible illustrated in FIG. 14, as viewed at an angle from above, illustrated essentially from the same direction as in FIGS. 11 to 13.

In general, at the coated sites, the ceramic had a wall thickness of about 5 mm to 50 mm and the silicon nitride layer had a thickness of 50 μm to 500 μm.

In the case of Quarzal crucibles for silicon production, the ceramic had, at the coated sites, a wall thickness of about 15 mm and the silicon nitride coating had a thickness of 100 μm to 300 μm.

In this case, the silicon nitride layer system was a multilayer system that acted as a barrier against the fused silicon.

The crucible was rectangular and had a depth of about 50 cm and a width of approximately 40 cm by 40 cm.

Further preferred dimensions for the rectangular crucible were preferably 650 to 950 mm for its first bottom side by 650 to 950 mm for its second bottom side and 400 to 600 mm in height for its side walls.

These crucibles were coated over their entire surface area or nearly their entire surface area in their interior, that is, with an upper edge of a few cm, that is, up to 10 cm, in such a manner that the layer lay within the specified deviations from the specified layer thickness.

Besides the above spatially resolved, pure thickness measurement, however, it was also possible to detect layer flaws, such as those occurring during delamination or cracking, for example, as shown below by the described figures by way of example.

FIG. 16 shows the intensity profile and hence the layer thickness profile, measured by pulse thermography, at the surface of another Quarzal crucible, which has a flawed silicon nitride layer, as viewed at an angle from above. To this end, cracks and delaminations were created in the coating in a defined manner.

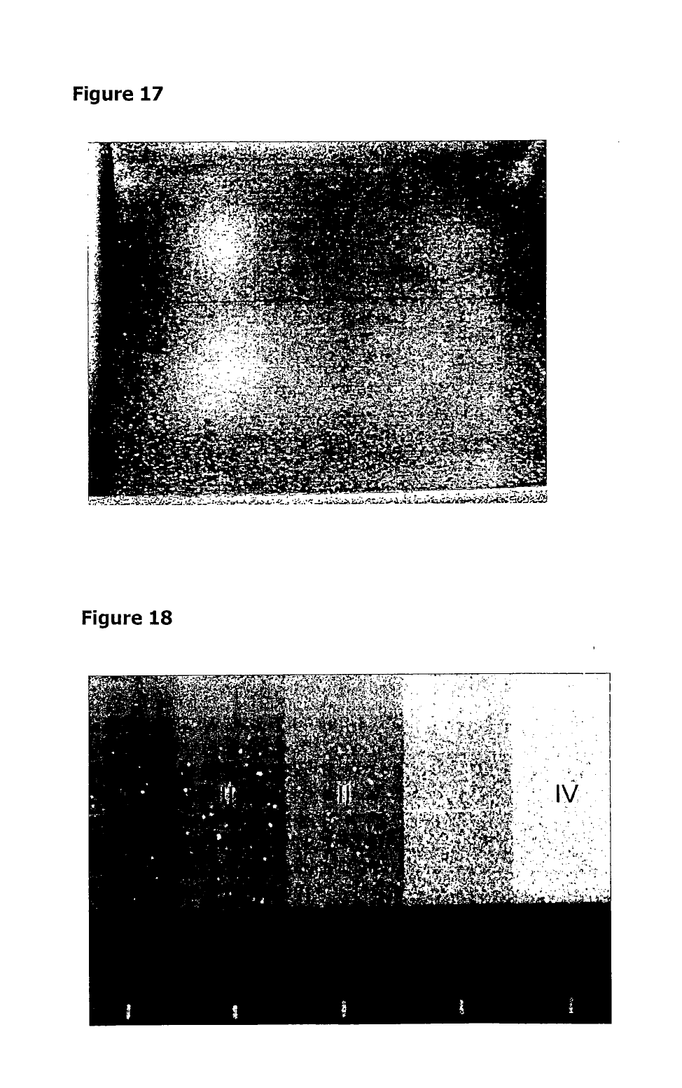

By contrast, FIG. 17 shows the local intensity profile and hence the layer thickness profile, measured by pulse thermography, at the surface of yet another Quarzal crucible, which has an intact silicon nitride layer, as viewed at an angle from above.

Through its method, the invention enables nonmetallic objects having a nonmetallic coating to be produced, in particular ceramic objects with a ceramic coating, which have particularly high layer quality and high service lives, particularly when the ceramic layer is used as barrier layer.

The inventors have shown that the material or the crucible material can also be composed of sintered silicon nitride, graphite, and/or fiber-reinforced graphite.

If the method according to the invention is used for the coating and prior to the thermal fixation of the ceramic layer, it is possible to detect sites with too little coating and to remedy them locally.

Accordingly, already prior to the thermal fixation, it can be ensured that a correct coating application, which has the specified layer thickness within the desired tolerances, is present.

In the case of a nonmetallic material, in particular fused quartz, Quarzal, sintered silicon nitride, graphite, and/or fiber-reinforced graphite, and a silicon nitride layer applied to it, a deviation of less than 20 μm from the specified layer thickness could be achieved. In most cases, this deviation was less than 5 μm from its specified layer thickness in a region of the surface of 10 by 10 cm, preferably of 100 by 100 cm.

It was even possible to maintain this precision essentially in the entire relevant coating region, particularly by subsequent coating application at sites with too little coating, particularly prior to thermal fixation thereof.

Understood as relevant coating region in this case is the region that later is brought into contact with the semiconductor melt and consequently has to provide the barrier properties. This relevant region can thus also have an upper edge of just a few cm, which still lies outside of this precise layer thickness.

The inventors were able to realize similarly good results using a thermographic lock-in method, in which, instead of a heat pulse, a periodic heat input in the form of, for example, a sine function in its temporal profile, was carried out and measured in a phase-synchronous manner.

Consequently, this method represents an outstanding means for inspecting the coating quality, in particular, also of ceramic barrier layers on ceramic substrates, including three-dimensional ceramic substrates.

Understood as ceramic materials or objects in the sense of the invention are also glass ceramic materials or objects.

The investigations and the securing of reproducible results of the inventors have made possible this success for the first time.

1-24. (canceled)

25. A method for the thermographic inspection of nonmetallic materials, comprising:
heating at least one part of a surface of the nonmetallic material with periodic heat inputs, the surface having a nonmetallic coating; and
recording a temporal and spatial temperature profile of the surface at least at a plurality of successive time points.

26. The method according to claim 25, wherein the step of heating with periodic heat inputs comprises heating with a short light pulse.

27. The method according to claim 25, further comprising using an imaging infrared camera to record the temporal and spatial temperature profile.

28. The method according to claim 25, further comprising:
determining, in a spatially resolved manner, a Fourier transform of the recorded temporal and spatial temperature profile; and
displaying in a spatially resolved manner for a certain phase or a certain time point following the input of the energy pulse and/or the convolution signal of the temporal profile of the energy pulse with the recorded temporal temperature profile is determined in a spatially resolved manner for a shift time point and displayed in a spatially resolved manner.

29. The method according to claim 25, wherein the nonmetallic material comprises a ceramic and the nonmetallic coating comprises a barrier coating.

30. The method according to claim 29, wherein the nonmetallic coating comprises a ceramic barrier coating.

31. The method according to claim 29, wherein the nonmetallic material comprises fused quartz, sintered silicon nitride, graphite, and fiber-reinforced graphite and the nonmetallic coating comprises a silicon nitride layer.

32. The method according to claim 31, wherein the silicon nitride layer comprises a ceramic silicon nitride layer.

33. A method for producing a nonmetallic material, comprising:
applying a suspension containing water and sinterable particles in a slurry to at least one part of a surface of the nonmetallic material by a process selected from the group consisting of spraying, brushing, rolling, dipping, and condensation of a laminar film; and
thermally affixing the suspension to the nonmetallic material to form a nonmetallic coating.

34. The method according to claim 33, wherein the sinterable particles comprise silicon nitride.

35. The method according to claim 33, wherein the nonmetallic material comprises a SiO₂-containing ceramic.

36. The method according to claim 33, further comprising:
heating the at least one part of the surface of the nonmetallic materials having the having a nonmetallic coating with periodic heat inputs; and
recording a temporal and spatial temperature profile of the surface at least at a plurality of successive time points.

37. The method according to claim 36, wherein the step of heating with periodic heat inputs comprises heating with a short light pulse.

38. The method according to claim 36, wherein the heating and recording steps are carried out prior to the thermal fixation step.

39. The method according to claim 36, further comprising drying the suspension before the heating and recording steps.

40. The method according to claim 39, wherein the drying step is carried out at a temperature of greater than 20° C. for a time period of at least 2 hours.

41. The method according to claim 35, wherein the ceramic has a wall thickness at the at least one part of about 5 mm to 50 mm and the silicon nitride coating has a thickness of 50 μm to 500 μm.

42. The method according to claim 35, wherein the ceramic has a wall thickness at the at least one part of about 15 mm and the silicon nitride coating has a thickness of 100 μm to 300 μm.

43. The method according to claim 33, further comprising repeating the applying and thermally affixing steps to provide a coating layer system.

44. The method according to claim 33, wherein the nonmetallic material has the form of a rectangular crucible having a bottom dimension of 650 to 950 mm by 650 to 950 mm and a height dimensions of 400 to 600 mm.

45. The method according to claim 33, further comprising associating the temporal and spatial temperature profile to a minimum layer thickness of the nonmetallic coating.

46. A method for measuring the layer thickness of a nonmetallic layer on a nonmetallic object, comprising:
heating at least one part of the nonmetallic layer on the nonmetallic object with periodic heat inputs; and
recording a temporal and spatial temperature profile of the surface at least at a plurality of successive time points.

47. The method according to claim 46, wherein the step of heating with periodic heat inputs comprises heating with a short light pulse.
